(19) United States
(12) Patent Application Publication
(10) Pub. No.: US 2015/0351283 A1
(43) Pub. Date: Dec. 3, 2015

(54) HEATSINK AND BOARD UNIT

(71) Applicant: FUJITSU LIMITED, Kawasaki-shi (JP)

(72) Inventors: Mitsutaka Yamada, Atsugi (JP); Shinichirou Okamoto, Yokohama (JP); Masumi Suzuki, Kawasaki (JP); Jie Wei, Hachioji (JP)

(73) Assignee: Fujitsu Limited, Kawasaki (JP)

(21) Appl. No.: 14/717,324

(22) Filed: May 20, 2015

(30) Foreign Application Priority Data
May 27, 2014 (JP) 2014-109080

(51) Int. Cl. H05K 7/20; F28F 3/12; F28F 13/08; F28F 3/04

(52) U.S. Cl. CPC H05K 7/20409; F28F 3/048; F28F 3/12; F28F 13/08

(57) ABSTRACT

A heatsink includes, a fin base that receives heat from a heat generating part; a cover that cooperates with the fin base to form a flow path of coolant along which the coolant flows; a plurality of fins formed on the fin base and partitioning the flow path into a plurality of small flow paths; and an adjustment plate vertically disposed between the fin base and the cover, and perpendicularly disposed with respect to the plurality of fins, wherein the adjustment plate including different height potions.

### CROSS-REFERENCE TO RELATED APPLICATION

This application is based upon and claims the benefit of priority from the prior Japanese Patent Application No. 2014-109080 filed on May 27, 2014, the entire contents of which are incorporated herein by reference.

### FIELD

The embodiments disclosed herein relate, for example, to a heatsink and a board unit.

### BACKGROUND

A structure is available wherein, in order to reduce a clearance provided between a tip end of a cooling plate (heat dissipation fin) and a heatsink, a coolant flow preventing member is provided in an opposing relationship to the heat dissipation fin in such a manner as to contact with the heat dissipation fin. Such a structure as just described is disclosed, for example, in Japanese Laid-open Patent Publication No. 2007-110025.

Also a structure is available wherein a groove of a heat dissipation member is covered with a lid member of copper, aluminum, steel, or plastic to form a cooling flow path. Such a structure as just described is disclosed, for example, in Japanese Laid-open Patent Publication No. 2004-6717.

### SUMMARY

In accordance with an aspect of the embodiments, a heatsink includes, a fin base that receives heat from a heat generating part; a cover that cooperates with the fin base to form a flow path of coolant along which the coolant flows; a plurality of fins formed on the fin base and partitioning the flow path into a plurality of small flow paths; and an adjustment plate vertically disposed between the fin base and the cover, and perpendicularly disposed with respect to the plurality of fins, wherein the adjustment plate including different height potions.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

These and/or other aspects and advantages will become apparent and more readily appreciated from the following description of the embodiments, taken in conjunction with the accompanying drawing of which:

FIG. 1 is a perspective view depicting a heatsink of a first embodiment;

FIG. 2 is an exploded perspective view depicting a heatsink of the first embodiment;

FIG. 3 is a perspective view depicting a cap in the first embodiment in a vertically reversed state;

FIG. 4 is a plan view depicting a heatsink of the first embodiment;

FIG. 5 is a front elevational view of a heatsink of the first embodiment;

FIG. 6 is a sectional view depicting a board including a heatsink of the first embodiment;

FIG. 7 is a sectional view depicting a board including a heatsink of a second embodiment;

FIG. 8 is a perspective view depicting a heatsink of a third embodiment;

FIG. 9 is a perspective view depicting a heatsink of a fourth embodiment; and

FIG. 10 is a perspective view partially depicting a heatsink of a fifth embodiment.

### DESCRIPTION OF EMBODIMENTS

A first embodiment is described in detail with reference to the drawings.

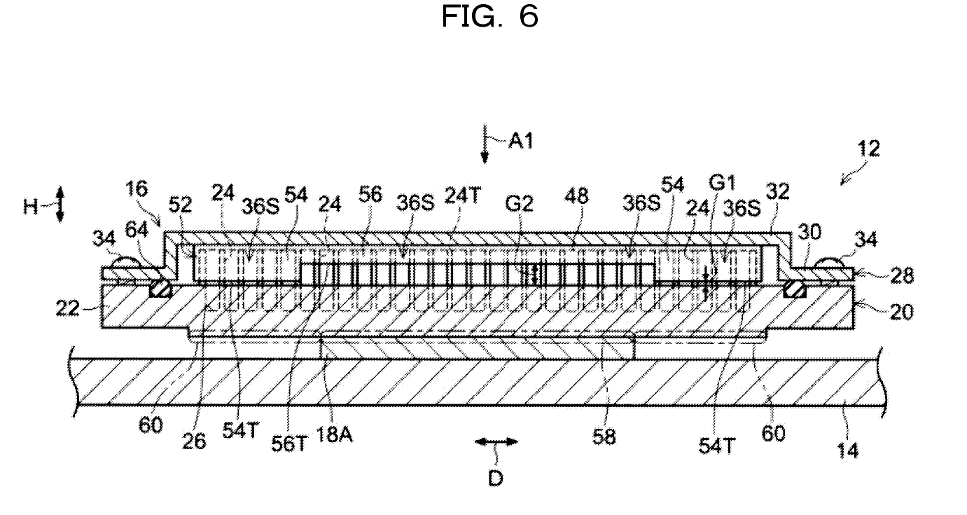

As depicted in FIG. 6, a board unit 12 of the first embodiment includes a board 14 and a heatsink 16. A heat generating part 18A that is a cooling target is mounted on the board 14. Although the heat generating part 18A may be, for example, a semiconductor chip of an integrated circuit or the like, the heat generating part 18A is not limited to the semiconductor chip.

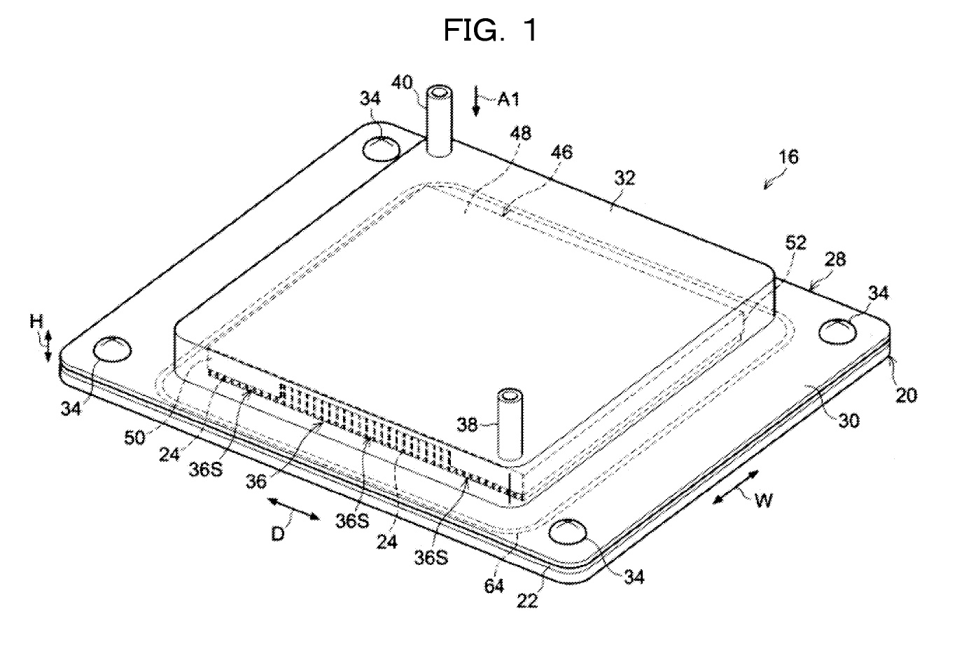

In FIG. 1, a widthwise direction, a depthwise direction, and a heightwise direction of the heatsink 16 are indicated by arrow marks W, D, and H, respectively. However, the directions mentioned are used for the convenience of description and do not limit directions of the heatsink 16 in an actual use state.

As depicted in FIGS. 1 to 5, the heatsink 16 includes a fin member 20. In the present embodiment, the fin member 20 is made of metal and includes a fin base 22 and a plurality of fins 24 formed on the fin base 22.

In the present embodiment, the fin base 22 is made of metal and formed in the shape of a plate. As recognized from FIG. 6, the fin base 22 contacts with the heat generating part 18A from the opposite side to the board 14 and receives heat of the heat generating part 18A. It is to be noted that some other member such as, for example, grease may be interposed between the heat generating part 18A and the fin base 22.

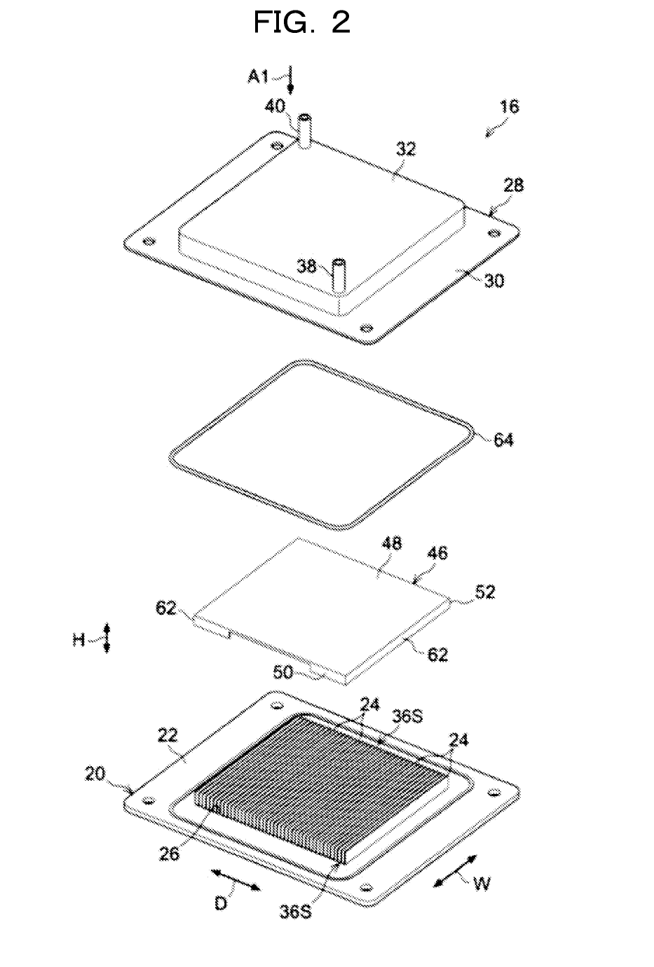

In the present embodiment, the fin base 22 has a rectangular shape (or a square shape) of a size greater than a size of the heat generating part 18A as viewed in a direction normal to the fin base 22 (direction indicated by an arrow mark A1). At a central location of a face of the fin base 22 on the opposite side to the face at which the fin base 22 contacts with the heat generating part 18A, a recess portion 26 is formed. The recess portion 26 has, in the present embodiment, a rectangular shape (or a square shape) of a size greater than the size of the heat generating part 18A as viewed in the direction indicated by the arrow mark A1 as may be recognized from FIGS. 2 and 6.

The heatsink 16 includes a cover 28. The cover 28 includes an outer frame portion 30 positioned at an outer peripheral portion thereof as viewed in the direction indicated by the arrow mark A1, and a cover main body 32 positioned at a central location of the cover 28 in a spaced relationship from the fin base 22 farther than the outer frame portion 30.

In a state in which the outer frame portion 30 opposes to the fin base 22, the cover 28 is attached to the fin base 22 by bolts 34. As a result, a coolant flow path 36 is formed between the fin base 22 and the cover main body 32.

The plurality of fins 24 each in the form of a plate are provided in such a manner as to extend uprightly from the recess portion 26 of the fin base 22. In the first embodiment, each of the fins 24 has a shape of a plate extending continuously in a flowing direction of coolant (in the direction indicated by the arrow mark W) in a small flow path 36S.

The plurality of fins 24 are disposed in parallel to each other in a spaced relationship from each other by a fixed distance in the depthwise direction (direction indicated by the arrow mark D). The coolant flow path 36 is partitioned into a plurality of small flow paths 36S by the plurality of fins 24.

An introduction path 38 and a discharge path 40 are formed on the cover main body 32 of the cover 28. The coolant flows into the coolant flow path 36 through the introduction path 38. The coolant flows out from the coolant flow path 36 through the discharge path 40.

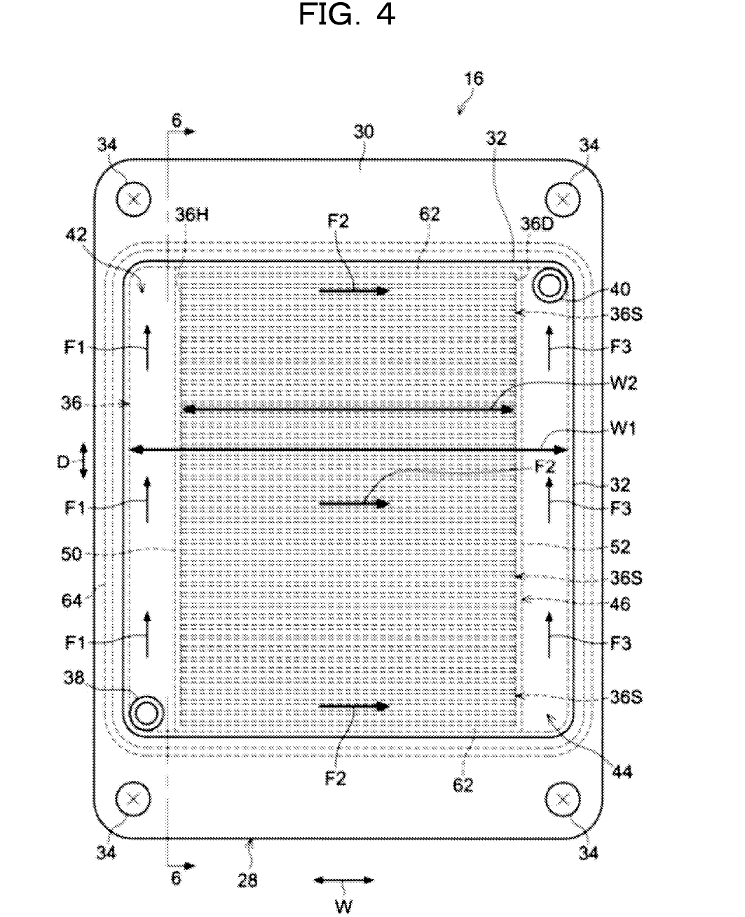

In the present embodiment, as recognized from FIG. 4, the introduction path 38 and the discharge path 40 are formed at diagonal corners of the cover main body 32 of the rectangular shape as viewed in the direction of the arrow mark A1. In the present embodiment, both of the introduction path 38 and the discharge path 40 are formed in a tubular shape.

As may be recognized from FIG. 4, a width W1 in inside dimension of the cover main body 32 is greater than a width W2 of the recess portion 26. An upstream common flow path 42 is formed at the upstream side (left side in FIG. 4) with respect to the small flow paths 36S. Further, a downstream common flow path 44 is formed at the downstream side (right side in FIG. 4) with respect to the small flow paths 36S. In particular, the coolant flowing into the upstream common flow path 42 from the introduction path 38 branches and flows into the small flow paths 36S (refer to an arrow mark F1). Then, the coolant flows separately along the small flow paths 36S (refer to an arrow mark F2). The coolant flowing through the small flow paths 36S merges in the downstream common flow path 44 and flows out from the discharge path 40 (refer to an arrow mark F3).

A cap 46 is disposed between the fin member 20 and the cover 28. In the first embodiment, the cap 46 includes an intermediate plate 48 in the form of a plate disposed between a tip end 24T of the fins 24 and the cover main body 32 of the cover 28.

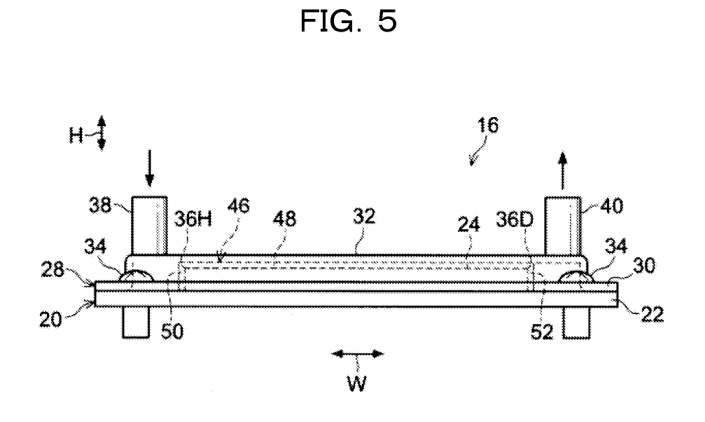

A pair of adjustment plates 50 and 52 extend from the opposite ends of the intermediate plate 48 in the widthwise direction. As recognized from FIGS. 4 and 5, the adjustment plate 50 is positioned in such a manner as to contact with an upstream side end portion of the fins 24 at an inlet 36H of the small flow paths 36S. The adjustment plate 52 is positioned in such a manner as to contact with a downstream side end portion of the fins 24 at an outlet 36D of the small flow paths 36S. It is to be noted that an adjustment plate may be disposed at the inlet 36H or the outlet 36D of the small flow paths 36S. The term “or” here is used to signify that the example described hereinabove wherein an adjustment plate is disposed at both of the inlet 36H and the outlet 36D of the small flow path 36S is included.

Both of the adjustment plates 50 and 52 include, at the opposite end sides thereof in the depthwise direction, a tall portion 54 having a great depth from the intermediate plate 48. The adjustment plates 50 and 52 further include, at a central portion thereof in the depthwise direction, a less tall portion 56 having a small depth from the intermediate plate 48. In other words, the adjustment plates 50 and 52 are shaped such that the adjustment plates 50 and 52 have two different depths (heights) at the tall portions 54 at the opposite side portions thereof and the less tall portion 56 at the central portion thereof.

As may be recognized from FIG. 6, a lower end 56T of the less tall portion 56 and a lower end 54T of the tall portions 54 are spaced from the fin base 22. Further, particularly a gap G1 between the lower end 54T of the tall portions 54 and the fin base 22 is smaller than a gap G2 between the lower end 56T of the less tall portion 56 and the fin base 22.

As may be recognized from FIG. 6, the adjustment plates 50 and 52 have a flow path sectional area that is reduced at the inlet 36H (upstream side) and the outlet 36D (downstream side) of each of the small flow paths 36S. Especially, since the tall portions 54 are deeper than the less tall portion 56, the flow path sectional area is smaller at the small flow paths 36S corresponding to the tall portions 54 than at the small flow paths 36S corresponding to the less tall portion 56.

The less tall portion 56 has a range substantially equal to or greater than a range of a position 58 at which the heat generating part 18A contacts with the fin base 22. On the other hand, the range of the tall portions 54 is within a range other than the range of the less tall portion 56, or in other words, is within a range of positions 60 at which the heat generating part 18A does not contact with the fin base 22. In particular, at the position 58 at which heat is received directly from the heat generating part 18A, the flow path sectional area of the small flow paths 36S is greater than that at the position 60 at which the amount of heat to be received is relatively small (the heat is not received directly).

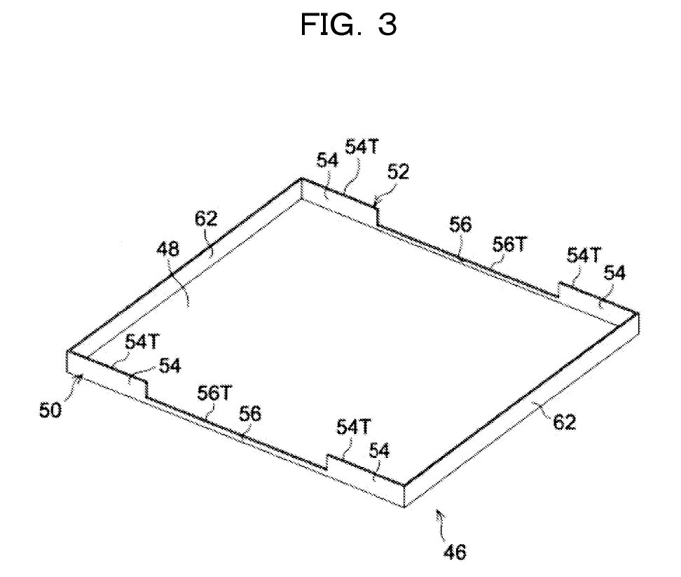

As may be recognized from FIGS. 2 and 3, the cover 28 includes two coupling plates 62 that couple the two adjustment plates 50 and 52 to each other. The adjustment plates 50 and 52 are coupled to each other by the coupling plates 62, and if the adjustment plates 50 and 52 and the coupling plates 62 are viewed in the direction indicated by the arrow mark A1, then the adjustment plates 50 and 52 and the coupling plates 62 have a rectangular shape.

In this manner, in the present embodiment, the cap 46 includes the intermediate plate 48, adjustment plates 50 and 52, and coupling plates 62. In other words, the cap 46 is structured such that the two adjustment plates 50 and 52 are integrated with each other by the intermediate plate 48 and the coupling plates 62, and the intermediate plate 48 is an example of a coupling unit.

Further, the cap 46 is configured such that the two adjustment plates 50 and 52 are coupled to each other by the coupling plates 62, and the coupling plates 62 are an example of a coupling unit.

As may be recognized from FIGS. 2, 4, and 6, a sealing member 64 that surrounds the coolant flow path 36 is disposed between the fin base 22 and the cover main body 32. The sealing member 64 suppresses leaking out of the coolant from the coolant flow path 36 past a clearance between the fin member 20 and the cover 28.

Now, operation of the present embodiment is described.

The coolant flow path 36 is partitioned into a plurality of small flow paths 36S by the fins 24. As may be recognized from FIG. 4, the coolant flowing in from the introduction path 38 is branched from the upstream common flow path 42 into and flows along the small flow paths 36S. Then, the coolant flowing separably along the small flow paths 36S merges at the downstream common flow path 44 and flows out from the discharge path 40.

The adjustment plate 50 is disposed at the inlet 36H (at the upstream side) of the small flow paths 36S while the adjustment plate 52 is disposed at the outlet 36D (at the downstream side). The small flow paths 36S have a flow path sectional area of the small flow paths 36S adjusted in response to the position of the small flow paths 36S by the tall portions 54 and the less tall portion 56. In particular, in the present embodiment, the flow path sectional area of the small flow paths 36S is greater at the central portion than at the opposite side portions of the adjustment plates 50 and 52 in the widthwise direction.

In particular, in the present embodiment, by disposing the adjustment plates 50 and 52, the flow rate of the coolant to flow along the small flow paths 36S may be adjusted in response to the position of the heat generating part 18A. In the example depicted in FIG. 6, at the position 58 at which the heat generating part 18A contacts, the small flow paths 36S have an increased flow path sectional area, and at the positions 60 at which the heat generating part 18A does not contact, the small flow paths 36S have a reduced flow path sectional area. Consequently, the position 58 to which a comparatively great amount of heat of the heat generating part 18A is transmitted may be cooled efficiently in comparison with an alternative structure that the small flow paths 36S have a uniform flow path sectional area.

In the present embodiment, the cap 46 is provided, and the two adjustment plates 50 and 52 are coupled to and integrated with each other by the intermediate plate 48 and the coupling plates 62. Accordingly, the number of parts is small in comparison with that in an alternative structure that the two adjustment plates 50 and 52 are formed as separate members from each other. Further, by placing the cap 46 on the overall plural fins 24, the adjustment plate 50 may be disposed at the upstream side of the small flow paths 36S and the adjustment plate 52 may be disposed at the downstream side of the small flow paths 36S.

The intermediate plate 48 is disposed between the tip end 24T of the plurality of fins 24 and the cover 28 and contacts with both of the tip end 24T of the fins 24 and the cover 28. Consequently, since the clearance between the tip end 24T of the fins 24 and the cover 28 may be minimized, inadvertent movement of the coolant between the small flow paths 36S may be suppressed.

Especially, since the intermediate plate 48 has elasticity in the thicknesswise direction, it contacts closely with and may minimize the clearance between the tip end 24T of the fins 24 and the cover 28. It is to be noted that, even if the cover 28 or the cap 46 has elasticity in the thicknesswise direction, a similar effect is created. Further, in this case, the disposition of the intermediate plate 48 may not be necessarily required.

Further, by assembling the cover 28 to the fin member 20 in a state in which the cap 46 is placed on the fins 24, the cap 46 is interposed between the plurality of fins 24 and the cover 28 upon assembly. Since the cap 46, particularly the intermediate plate 48, closely contacts with the fins 24 and the cover 28, positional displacement of the cover 28 with respect to the fin base 22 may be minimized.

The cover 28 includes the introduction path 38 for introducing the coolant into the coolant flow path 36. The number of parts in the present embodiment is small in comparison with that in an alternative structure that the introduction path 38 is formed as a separate member from the cover 28. Similarly, the cover 28 includes the discharge path 40 from which the coolant from the coolant flow path 36 flows out. The number of parts in the present embodiment is small in comparison with that in an alternative structure that the discharge path 40 is formed as a separate member from the cover 28.

As may be recognized from FIG. 4, the introduction path 38 extends in a direction normal to the fin base 22 from the fin base 22. In comparison with an alternative structure that the introduction path 38 extends in a direction intersecting with the normal direction to the fin base 22, when the heatsink 16 is viewed in the direction indicated by the arrow mark A1, the introduction path 38 does not protrude and may be reduced in size. Similarly, the discharge path 40 extends in the normal direction to the fin base 22 from the fin base 22. In comparison with an alternative structure that the discharge path 40 extends in a direction intersecting with the normal direction to the fin base 22, when the heatsink 16 is viewed in the direction indicated by the arrow mark A1, the discharge path 40 does not protrude and may be reduced in size.

Now, a second embodiment is described. In the second embodiment, like elements and members to those in the first embodiment are denoted by like reference characters, and description of the like elements and members is omitted herein suitably.

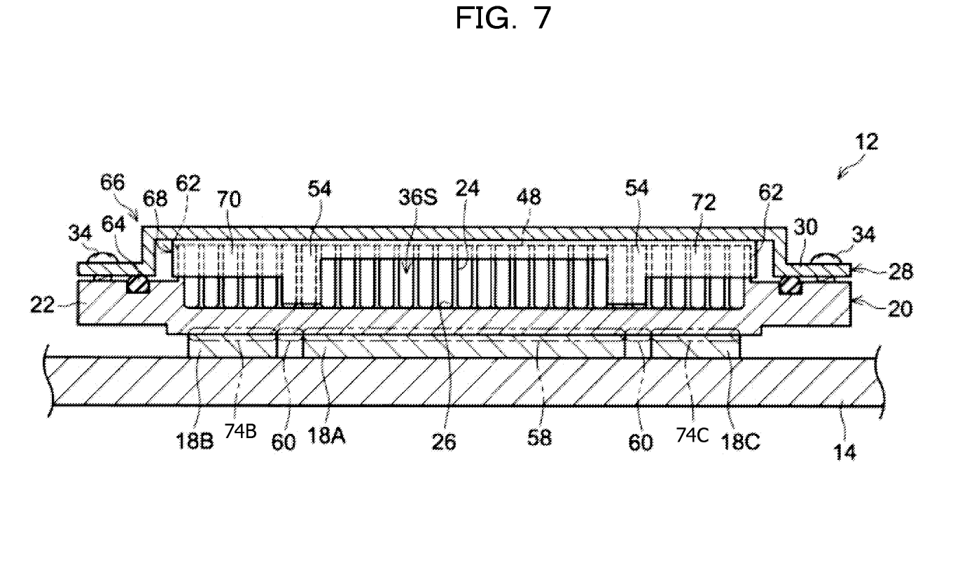

As depicted in FIG. 7, in the second embodiment, heat generating parts 18B and 18C are mounted on the board 14 in addition to the heat generating part 18A. Although the heat generating parts 18B and 18C are positioned, in the example of FIG. 7, at the opposite sides of the heat generating part 18A, the positions of the heat generating parts 18B and 18C are not limited. It is assumed that the heat generation amount of the heat generating parts 18B and 18C is smaller than the heat generation amount of the heat generating part 18A.

On a cap 68 of a heatsink 66 of the second embodiment, intermediate back portions 70 and 72 having a depth intermediate between the heights of the tall portions 54 and the less tall portion 56 are formed on the adjustment plate 50. As may be recognized from FIG. 7, the positions of the intermediate back portions 70 and 72 are positions 74B and 74C at which the heat generating parts 18B and 18C contact with the fin base 22, respectively.

The intermediate back portions 70 and 72 have a depth intermediate between the depths of the tall portions 54 and the less tall portion 56, and the small flow paths 36S corresponding to the intermediate back portions 70 and 72 have a flow path sectional area intermediate between the flow path sectional areas of the small flow paths 36S corresponding to the tall portions 54 and the flow path sectional areas of the small flow paths 36S corresponding to the less tall portion 56.

Also in the second embodiment, by disposing the adjustment plates 50 and 52, the flow rate of the coolant to flow along the small flow paths 36S may be adjusted in response to the position of the small flow paths 36S.

In the second embodiment, since the fin base 22 contacts with the heat generating parts 18A, 18B, and 18C, the plurality of heat generating parts 18A, 18B, and 18C may be cooled.

Especially, in the second embodiment, for example, at the position 58 at which the heat generating part 18A contacts, the small flow paths 36S have an increased flow path sectional area, and at the position 60 at which the heat generating parts 18A, 18B, and 18C do not contact, the small flow paths 36S have a reduced flow path sectional area. Further, at the positions 74B and 74C at which the heat generating parts 18B and 18C contact, respectively, the small flow paths 36S have a flow path sectional area intermediate between the flow path sectional area of the small flow paths 36S corresponding to the tall portions 54 and the flow path sectional area of the small flow paths 36S corresponding to the less tall portion 56. By setting the depth (height) of the adjustment plate 50 to different heights in accordance with the plurality of heat generating parts 18A, 18B, and 18C in this manner, the plurality of heat generating parts 18A, 18B, and 18C may be cooled efficiently in response to the heat generation amount thereby.

Now, a third embodiment is described. In the third embodiment, like elements and members to those in the first embodiment are denoted by like reference characters, and description of the like elements and members is omitted herein suitably. Further, in the third to fifth embodiments, while the structure of the cap is different, the structure of the heatsink and the board may be made same. Therefore, the heatsink and the board are not depicted.

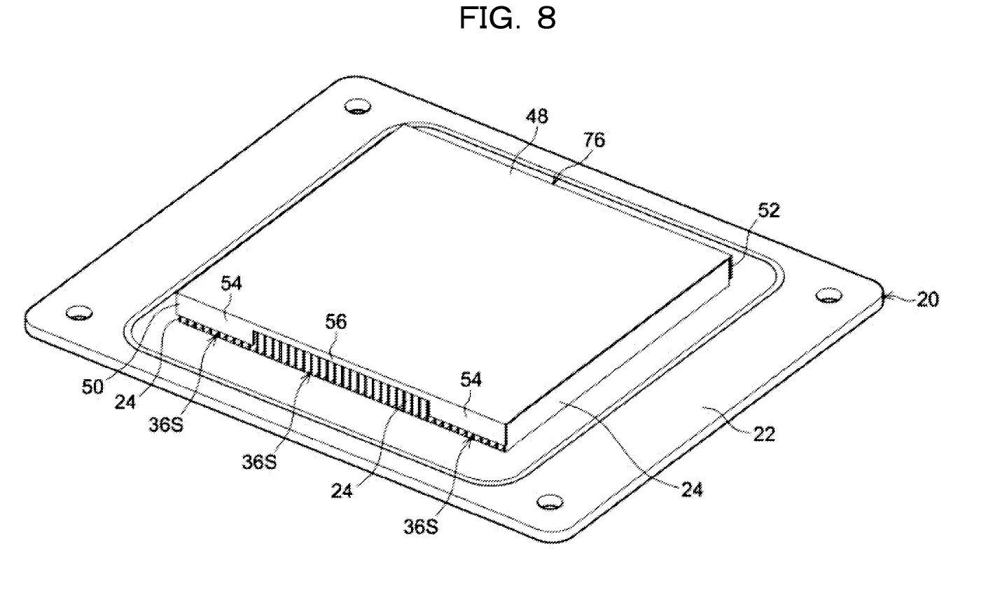

As depicted in FIG. 8, a cap 76 in the third embodiment includes the adjustment plates 50 and 52 and the intermediate plate 48. In other words, the cap 76 is structured such that the two adjustment plates 50 and 52 are integrated with each other by the intermediate plate 48.

Accordingly, in the third embodiment, since the two adjustment plates 50 and 52 are integrated with each other by the intermediate plate 48, the number of parts is reduced in comparison with that in an alternative structure that the adjustment plates 50 and 52 are formed as separate members from each other.

Since the cap 76 in the third embodiment does not include the coupling plates 62 (refer to FIG. 2 and so forth), the cap 76 may achieve reduction in weight in comparison with an alternative structure that includes the coupling plates 62.

Further, in the third embodiment, the intermediate plate 48 is included. The intermediate plate 48 is provided between and contacts with both of the tip end 24T of the plurality of fins 24 and the cover 28. Since the clearance between the tip end 24T of the fins 24 and the cover 28 may be minimized, inadvertent movement of the coolant between the small flow paths 36S may be minimized.

Especially, the intermediate plate 48 has elasticity in the thicknesswise direction thereof and closely contacts with the tip end 24T of the fins 24 and the cover 28. Consequently, the clearance between the tip end 24T of the fins 24 and the cover 28 may be minimized.

Now, a fourth embodiment is described. In the fourth embodiment, like elements and members to those in the first embodiment are denoted by like reference characters, and description of the like elements and members is omitted herein suitably.

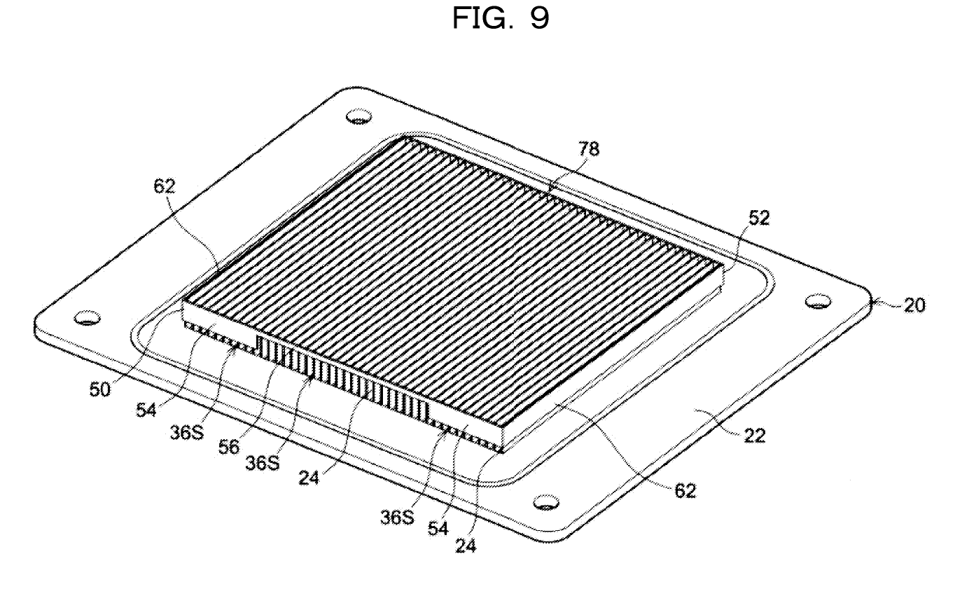

As depicted in FIG. 9, a cap 78 in the fourth embodiment includes the adjustment plates 50 and 52 and the coupling plates 62. The cap 78 has a form of a frame wherein the two adjustment plates 50 and 52 are coupled to and integrated with each other by the coupling plates 62.

Accordingly, in the fourth embodiment, since the two adjustment plates 50 and 52 are integrated with each other by the coupling plates 62, the number of parts is reduced in comparison with that of an alternative structure that the adjustment plates 50 and 52 are formed as separate members from each other.

The cap 78 in the fourth embodiment does not include the intermediate plate 48 (refer to FIG. 2), and therefore, reduction in weight may be anticipated in comparison with an alternative structure that includes the intermediate plate 48.

It is to be noted that, in contrast, the cap 46 in the first embodiment is structured such that the adjustment plates 50 and 52 are coupled to each other by the intermediate plate 48 and the coupling plates 62, and therefore, the cap 46 has high bending rigidity as a whole and is stable in shape.

In the first to fourth embodiments described above, the plurality of fins 24 individually extend continuously along the flowing direction of the coolant. Further, the plurality of fins 24 are disposed in a spaced relationship from each other by a fixed distance in a direction perpendicular to the flowing direction of the coolant. Consequently, the plurality of small flow paths 36S may be formed uniformly by the fins 24. Therefore, the coolant flowing along the small flow paths 36S having a desired flow path sectional area (flow rate of the coolant) may be inhibit from inadvertently moving to an adjacent small flow path 36S by the fins 24.

Now, a fifth embodiment is described. In the fifth embodiment, like elements and members to those in the first embodiment are denoted by like reference characters, and description of the like elements and members is omitted herein suitably.

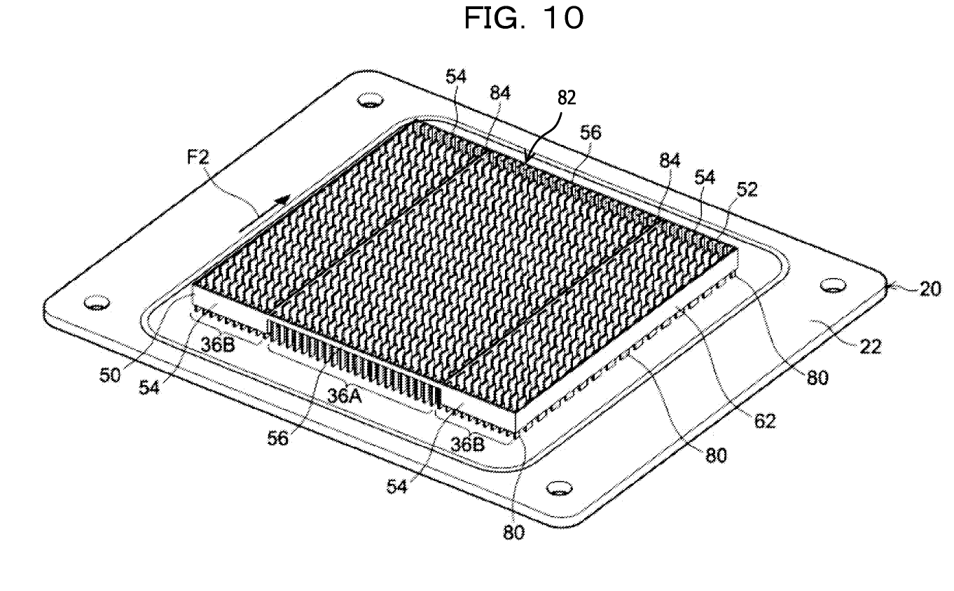

As depicted in FIG. 10, a fin 80 in the fifth embodiment is shaped such that it is divided into a plurality of portions in the flowing direction of the coolant (direction indicated by an arrow mark F2) along the small flow path 36S.

A cap 82 in the fifth embodiment includes adjustment plates 50 and 52, coupling plates 62, and two partition plates 84. Each of the partition plates 84 extends continuously from a boundary of the adjustment plate 50 between one of the tall portions 54 and the less tall portion 56 and a boundary of the adjustment plate 52 between the other tall portion 54 and the less tall portion 56.

In the fifth embodiment, the coolant flow path 36 includes a region 36A and regions 36B formed by the tall portions 54 and the less tall portion 56. The small flow paths 36S in the region 36A have a great flow path sectional area while the small flow paths 36S in the regions 36B have a small flow path sectional area. Therefore, even if the fins 80 are divided in the direction indicated by the arrow mark F2, movement of the coolant between the region 36A and the regions 36B is suppressed by the partition plates 84.

Therefore, also in the fifth embodiment, the flow rate of the coolant to flow along the small flow paths 36S may be adjusted in response to the position of the small flow paths 36S.

It is to be noted that the cap in the fifth embodiment may be structured in such a manner as to include the intermediate plate 48 depicted in FIG. 2, 3, or 8. Further, the cap in the fifth embodiment may be structured in such a manner as not to include the coupling plates 62.

In all of the embodiments described above, in order to adjust the flow rate of the coolant along the small flow paths 36S, only it may be necessary to dispose the adjustment plates 50 and 52. In other words, any other member than the adjustment plates 50 and 52 may not be required, and therefore, simplification in structure of the small flow paths 36S (coolant flow path 36) may be anticipated and reduction of the cost may be anticipated.

In the foregoing description, an example is described wherein the adjustment plates 50 and 52 are provided at the upstream side and the downstream side, respectively, of the small flow paths 36S in the flowing direction of the coolant (direction indicated by the arrow mark F2). However, only the adjustment plate 50 at the upstream side or the adjustment plate 52 at the downstream side may be provided. Further, a different adjustment plate may be provided at a central location in the flowing direction of the coolant. Where the adjustment plates 50 and 52 are provided at both of the upstream side and the downstream side of the coolant flow path 36 in the flowing direction of the coolant (direction indicated by the arrow mark F2), the flow path sectional area of the small flow paths 36S may be adjusted at both of the upstream side and the downstream side of the small flow paths 36S.

Although the embodiments of the technology disclosed in the specification are described above, the technology disclosed in the specification is not limited to them, but it is a matter of course that the technology disclosed in the specification may be carried out in various modified forms without departing from the subject matter thereof in addition to the embodiments described above.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A heatsink comprising:
a fin base that receives heat from a heat generating part;
a cover that cooperates with the fin base to form a flow path of coolant along which the coolant flows;
a plurality of fins formed on the fin base and partitioning the flow path into a plurality of small flow paths; and
an adjustment plate vertically disposed between the fin base and the cover, and perpendicularly disposed with respect to the plurality of fins, wherein the adjustment plate including different height potions.

2. The heatsink according to claim 1,
wherein the different height potions of the adjustment plate are configured to adjust a sectional area of the small flow paths.

3. The heatsink according to claim 1,
the adjustment plate disposed at at least one of an inlet and an outlet of the small flow paths.

4. The heatsink according to claim 1,
wherein the plurality of fins are formed on the fin base in such a manner as to extend continuously along a flowing direction of the coolant and be disposed in a spaced relationship from each other in a direction perpendicular to the flowing direction.

5. The heatsink according to claim 3,
wherein the adjustment plate configured to be disposed at both of the inlet and the outlet.

6. The heatsink according to claim 5,
wherein an inlet side and an outlet side of the adjustment place are coupled to each other by a coupling unit vertically disposed between the fin base and the cover, and disposed in parallel to the plurality of fins.

7. The heatsink according to claim 6, further comprising:
an intermediate plate disposed between a top of the plurality of fins and the cover, and in a clearance between the fins and the cover.

8. The heatsink according to claim 7,
wherein at least of one of the intermediate plate, the cover and the adjustment plate has elasticity.

9. The heatsink according to claim 1,
wherein the cover includes an introduction path and a discharge path for the coolant.

10. The heatsink according to claim 9,
wherein the introduction path and the discharge path extend in a direction normal to the fin base.

11. A board unit, comprising:
a board on which a heat generating part is mounted;
a fin base that receives heat from a heat generating part;
a cover that cooperates with the fin base to form a flow path of coolant along which the coolant flows;
a plurality of fins formed on the fin base and partitioning the flow path into a plurality of small flow paths; and
an adjustment plate vertically disposed between the fin base and the cover, and perpendicularly disposed with respect to the plurality of fins, wherein the adjustment plate including different height potions.

12. The board unit according to claim 11,
wherein the different height potions of the adjustment plate are configured to adjust a sectional area of the small flow paths.

13. The board unit according to claim 11,
the adjustment plate disposed at at least one of an inlet and an outlet of the small flow paths.

14. The board unit according to claim 11,
wherein the plurality of fins are formed on the fin base in such a manner as to extend continuously along a flowing direction of the coolant and be disposed in a spaced relationship from each other in a direction perpendicular to the flowing direction.

15. The board unit according to claim 13,
wherein the adjustment plate configured to be disposed at both of the inlet and the outlet.

16. The board unit according to claim 15,
wherein an inlet side and an outlet side of the adjustment place are coupled to each other by a coupling unit vertically disposed between the fin base and the cover, and disposed in parallel to the plurality of fins.

17. The board unit according to claim 16, further comprising:
an intermediate plate disposed between a top of the plurality of fins and the cover, and in a clearance between the fins and the cover.

18. The board unit according to claim 17,
wherein at least of one of the intermediate plate, the cover and the adjustment plate has elasticity.

19. The board unit according to claim 11,
wherein the cover includes an introduction path and a discharge path for the coolant.

20. A method of cooling comprising:
receiving, by a fin base of a heatsink, heat of a heat generating part;
forming, by a cover of the heatsink cooperating with the fin base, a flow path of coolant along which the coolant flows;
partitioning, by a plurality of fins formed on the fin base of the heatsink, the flow path into a plurality of small flow paths; and
adjusting, an adjustment plate vertically disposed between the fin base and the cover, and perpendicularly disposed with respect to the plurality of fins, wherein the adjustment plate including different height potions, the small flow paths.
